(19) United States
(12) Patent Application Publication
(10) Pub. No.: US 2010/0079937 A1
(43) Pub. Date: Apr. 1, 2010

(54) KEYBOARD ADAPTER AND ELECTRONIC APPARATUS

(75) Inventors: Yuta IIZUKA, Kawasaki (JP); Masuo OHNISHI, Kawasaki (JP)

Correspondence Address: Fujitsu Patent Center;C/O CPA Global, P.O. Box 52050, Minneapolis, MN, 55402, US

(73) Assignee: FUJITSU LIMITED, Kawasaki (JP)

(21) Appl. No.: 12/565,965

(22) Filed: Sep. 24, 2009

(30) Foreign Application Priority Data
Sep. 30, 2008 (JP) 2008-254593

(51) Int. Cl. H05K 5/00

(52) U.S. Cl. 361/679.08

(57) ABSTRACT

A keyboard adapter includes a first surface for fixing a keyboard; a second surface fixed to an apparatus body for allowing to separate with keyboard; and a body fixing portions for fixing the apparatus body to the second surface.

### CROSS-REFERENCE TO RELATED APPLICATION

This application is based upon and claims the benefit of priority of the prior Japanese Patent Application No. 2008-254593, filed on Sep. 30, 2008, the entire contents of which are incorporated herein by reference.

### FIELD

The embodiments discusses herein is related to an electronic apparatus including a keyboard.

### BACKGROUND

As an electronic apparatus, the one in which a keyboard is employed for performing an input operation is known. The keyboard is mounted at a predetermined position in an apparatus body. Mounting of the keyboard to the apparatus body is achieved by screws, claws, or the like. (e.g. Japanese Laid-open Patent Publication No. 07-58480, Japanese Laid-open Patent Publication No. 07-245492, and Japanese Laid-open Patent Publication No. 09-64562)

In such an electronic apparatus, there is a case in which the design is modified to achieve a model change. When the design of the apparatus body is modified because of the model change, it may modify the design of the keyboard as well in order to allow the same to be mounted on the apparatus body which is changed in design. Also, it may newly manufacture the apparatuses body and the keyboard which are changed in design. In other words, it may modify the design of the keyboard and manufacture the same again every time when the design of the apparatus body is modified. In this manner, newly modifying the design of the keyboard and manufacturing the same has been a factor of increase in manufacturing cost of the electronic apparatus.

### SUMMARY

According to an aspect of the embodiment, an a keyboard adapter includes a first surface for fixing a keyboard; a second surface fixed to an apparatus body for allowing to separate with keyboard; and a body fixing portions for fixing the apparatus body to the second surface.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of a laptop personal computer according to an embodiment.

FIG. 2 is an exploded perspective view of a main body portion.

FIGS. 3A and 3B are a perspective view for explaining an assembly of a keyboard to the main body portion.

FIG. 4 is a cross-sectional view for explaining the assembly of the keyboard to the main body portion.

FIG. 5 is a cross-sectional view for explaining a fixation of a keyboard having a different shape.

FIG. 6 is a drawing of a keyboard having a different shape viewed from a back surface side.

FIG. 7 is an explanatory drawing of an adapter according to a first modification.

FIG. 8 is an explanatory drawing of an adapter according to a second modification.

FIGS. 9A and 9B are an explanatory drawing of an adapter according to a third modification.

FIGS. 10A and 10B are an explanatory drawing of an adapter according to a fourth modification.

FIG. 11 is a cross-sectional view of the adapter in a state in which the electronic components are integrated in the adapter according to the fourth embodiment.

FIG. 12 is a cross-sectional view for explaining an adapter according to a fifth modification.

### DESCRIPTION OF EMBODIMENTS

Embodiments of the present invention will be described below.

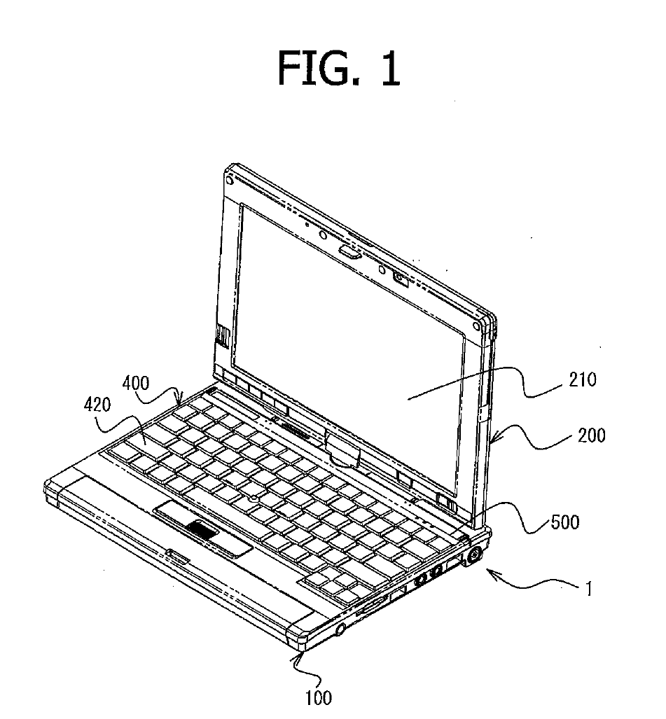

FIG. 1 is a perspective view of a laptop personal computer (electronic apparatus) 1 according to this embodiment. The laptop personal computer 1 includes a main body portion (apparatus body) 100 and a display unit 200 connected so as to be openable and closable by a hinge or the like, not illustrated. The main body portion 100 includes a keyboard 400 which functions as an operating unit mounted on the main body portion 100. The keyboard 400 includes a plurality of arranged keys 420. The main body portion 100 includes a CPU (Central Processing Unit) for controlling an operation of an entire laptop personal computer 1, a ROM (Read Only Memory), and a RAM (Random Access Memory) integrated therein.

The display unit 200 includes a display 210 for displaying predetermined images mounted thereon. A desired image is displayed on the display 210 according to an input operation via the keyboard 400. The display 210 is, for example, a liquid crystal display, a plasma display, or a CRT (Cathode Ray Tube) display. The keyboard 400 is mounted on the main body portion 100 by an adapter 300 and a fixing member 500.

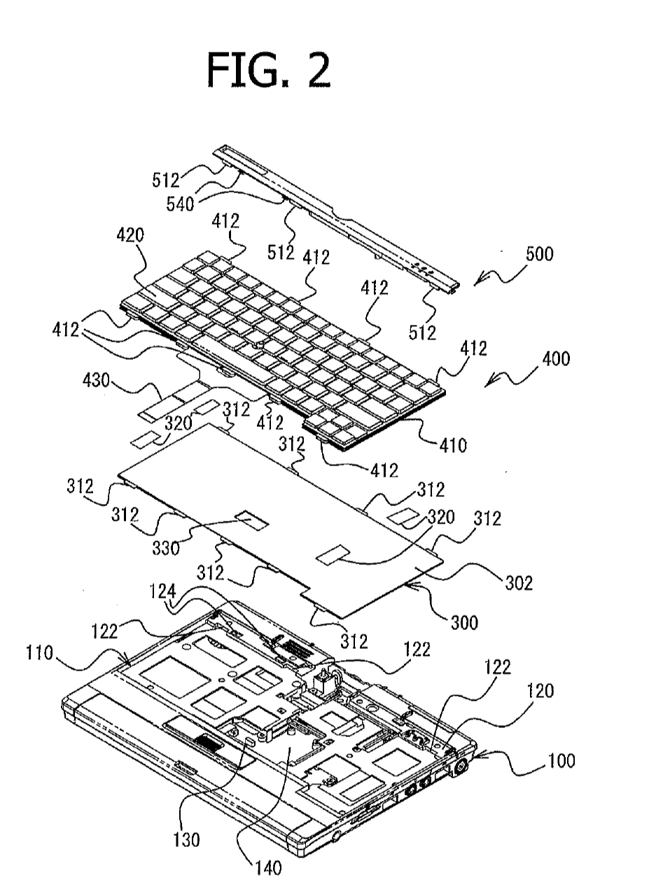

FIG. 2 is an exploded perspective view of the main body portion 100. The display unit 200 is omitted. The main body portion 100 includes a substrate 140 integrated therein. The substrate 140 includes a connector 130 in addition to electronic components such as the CPU. The substrate 140 is a hard printed board formed of a base material formed of polyimide resin, epoxy resin, glass epoxy resin, and so on.

The keyboard 400 is mounted on a mounting portion 110 positioned on an upper surface of the main body portion 100. An assembling portion 120 is provided on the mounting portion 110 at a position near the display unit 200. The assembling portion 120 extends so as to extend along the direction of a shaft for connecting the main body portion 100 and the display unit 200 so as to be openable and closable. The assembling portion 120 constitutes part of a casing of the main body portion 100. A plurality of concave portions 122 are formed along the longitudinal direction at an end of the assembling portion 120 on the side of the mounting portion 110. A plurality of engaging holes 124 are provided along the longitudinal direction of the assembling portion 120.

The keyboard 400 is fixed to the adapter 300 by a double-sided adhesive tape 320. The adapter 300 is formed into a thin panel shape. The adapter 300 includes a plurality of projections 312 provided at an edge thereof and a clearance hole 330 provided at a substantially center thereof. The projections 312 project outward from the edge. The projections 312 are formed into complementary structures with respect to the concave portions 122. By the engagement between the concave portions 122 and the projections 312, the position of the adapter 300 with respect to the main body portion 100 is defined.

The keyboard 400 is fixed to a front surface 302. The material of the adapter 300 may be a synthetic resin, and may be a metal. When the material of the adapter 300 is the synthetic resin, a resin superior in heat resistance is preferably used considering heat discharge from the electronic components integrated in the main body portion 100.

The keyboard 400 includes a substrate 410, the plurality of keys 420 arranged on the substrate 410, projections 412 provided across the edge of the substrate 410 at nine positions, and a cable 430 for securing electrical connection between the substrate 410 and the main body portion 100. The substrate 410 is switched by operating the plurality of keys 420.

The projections 412 project outward from the edge of the substrate 410. The projections 412 are formed into substantially the same shape as the projections 312. The number of the projections 412 are the same as the number of the projections 312. By the engagement between the projections 412 and the concave portions 122, the position of the keyboard 400 with respect to the main body portion 100 is defined.

The cable 430 is a circuit substrate having flexibility and is also referred to as a flexible printed board. The cable 430 passes through the clearance hole 330 and is connected to the connector 130. Accordingly, the electrical connection between the main body portion 100 and the keyboard 400 is ensured. The clearance hole 330 functions as a clearance portion for avoiding interference between the cable 430 and the adapter 300.

The fixing member 500 is formed into an elongated shape. The fixing member 500 is formed of a synthetic resin. The fixing member 500 is provided with a plurality of pressing portions 512 across the longitudinal direction thereof. The pressing portions 512 project downward from a bottom surface of the fixing member 500. The pressing portions 512 are engageable with the concave portions 122. Claw portions 540 are provided on the bottom surface of the fixing member 500. The claw portions 540 are engageable with the engaging holes 124 of the assembling portion 120. More specifically, the claw portions 540 and the engaging holes 124 engage by snap-fitting with respect to each other.

A method of assembling the main body portion 100 will be described. First of all, the double-sided adhesive tape, not illustrated, is bonded to the front surface 302 so as to avoid the clearance hole 330. Subsequently, in a state in which the cable 430 is passed through the clearance hole 330, the keyboard 400 is fixed to the front surface 302 so as to match the positions of the projections 312 and the projections 412. In other words, the projections 312 function as positioning portions for positioning the same with respect to the keyboard 400. The keyboard 400 is fixed to the front surface 302 by the double-sided adhesive tape.

Subsequently, the adapter 300 and the keyboard 400 are assembled to the mounting portion 110 of the main body portion 100 by aligning the projections 312, 412 with the concave portions 122. In this state, the adapter 300 and the keyboard 400 are not fixed to the mounting portion 110, and are in a removable state. Subsequently, the pressing portions 512 are aligned with the concave portions 122, and the claw portions 540 are aligned with the engaging holes 124, whereby the fixing member 500 is assembled to the main body portion 100. Since the claw portions 540 engage the engaging holes 124, the fixing member 500 is fixed to the main body portion 100, and the pressing portions 512 press the projections 312, 412. Since the pressing portions 512 press the projections 312, 412, the adapter 300 and the keyboard 400 are fixed to the main body portion 100 by the fixing member 500. In this manner, the main body portion 100 is assembled.

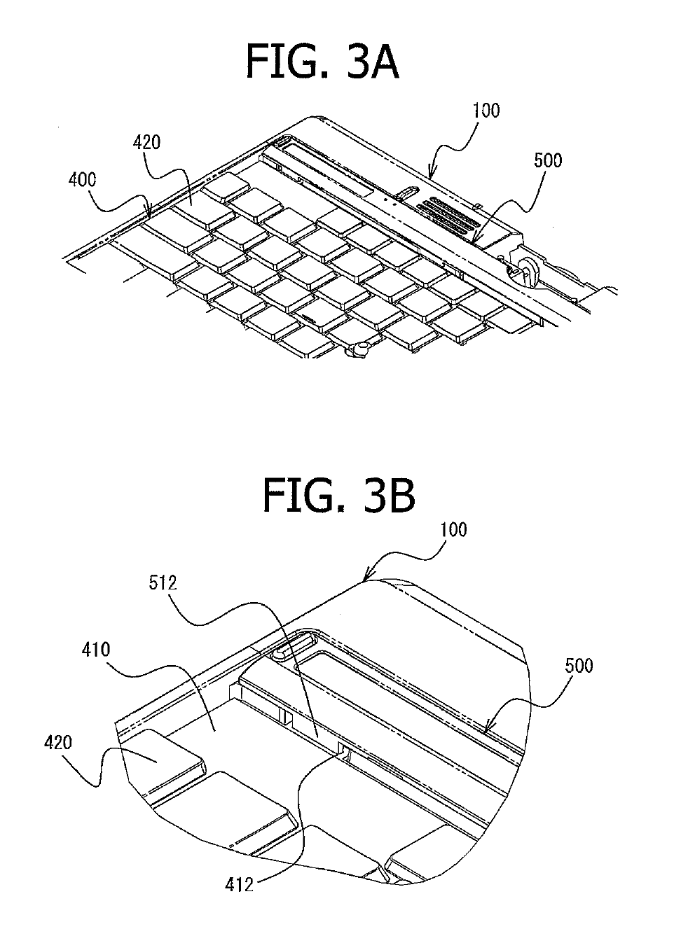

FIGS. 3A and 3B are a perspective view for explaining the assembly of the keyboard 400 to the main body portion 100. FIG. 3A is a perspective view illustrating part of the main body portion 100 after the assembly. FIG. 3B is an enlarged view of a periphery of the projections 412. For easy understanding, part of the keys 420 is omitted in the drawing. As illustrated in FIG. 3A and FIG. 3B, the pressing portions 512 presses the projections 412 toward the main body portion 100. Therefore, the pressing portions 512 function as keyboard pressing portions for pressing the keyboard 400 against the main body portion 100.

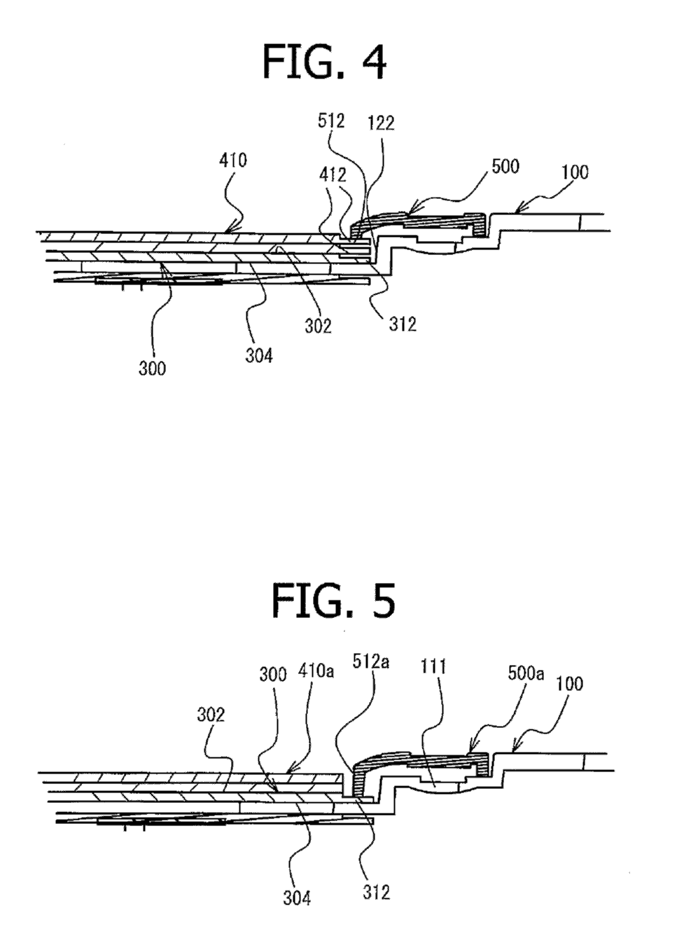

FIG. 4 is a cross-sectional view for explaining the assembly of the keyboard 400 to the main body portion 100 by the fixing member 500 and the adapter 300. In FIG. 4, the keys 420 of the keyboard 400 are omitted. By the pressing portions 512 press the upper surfaces of the projections 412 toward the main body portion 100, the adapter 300 and the keyboard 400 are fixed to the main body portion 100. Therefore, the pressing portions 512 function as adapter pressing portions for pressing the adapter 300 against the main body portion 100. The projections 312 are pressed by the pressing portions 512 indirectly via the projections 412. Therefore, the projections 312 function as main body fixing portions for fixing a back surface 304 of the adapter 300 to the main body portion 100.

The keyboard 400 in this embodiment is not fixed directly to the main body portion 100, and is fixed to the main body portion 100 via the adapter 300. Therefore, even when the design of the main body portion 100 is modified, the same keyboard 400 may be fixed to the main body portion modified in design by changing the shape of the adapter 300 or the like. Accordingly, the same keyboard may be mounted on the main body portion modified in design. Therefore, it may not be necessary to modify the design of the keyboard newly and manufacture the same, so that the manufacturing cost of the entire laptop personal computer 1 is restrained.

Also, when the keyboard 400 is fixed to the main body portion 100 directly by the screws or the claws, a key-stroke feeling of the keyboard 400 varies depending on the fixing positions. In other words, the key-stroke feeling is different between the positions near the fixing positions and positions apart from the fixing positions and the user has an uncomfortable feeling. However, the keyboard 400 is not fixed directly to the main body portion 100, and is fixed to the adapter 300 with the double-sided adhesive tape. Therefore, the keyboard 400 is held by the entire front surface 302 of the adapter 300, and hence the key-stroke feeling is substantially uniformized irrespective of the operating position.

Subsequently, the fixation of the keyboard having a different shape from the keyboard 400 will be described. FIG. 5 is a cross-sectional view for explaining the fixation of the keyboard having a different shape. FIG. 5 corresponds to FIG. 4, and the keys 420 are omitted. As illustrated in FIG. 5, a substrate 410a does not have the projections 412. The fixation between the adapter 300 and the substrate 410a is achieved by the double-sided adhesive tape, but may be fixed by an adhesive agent or fusion bonding. As illustrated in FIG. 5, the substrate 410a is not provided with the projections 412 unlike the case described above. In other words, the pressing portions 512 directly press the projections 312. Therefore, the projections 312 function as the main body fixing portions for fixing a back surface 304 of the adapter 300 to the main body portion 100. The keyboard 400a as described above may also be fixedly mounted on the main body portion 100. The adapter 300 mounted on the main body portion 100 in this manner may be separated from the main body portion 100 together with the keyboard 400 by following the procedure in the inverse order.

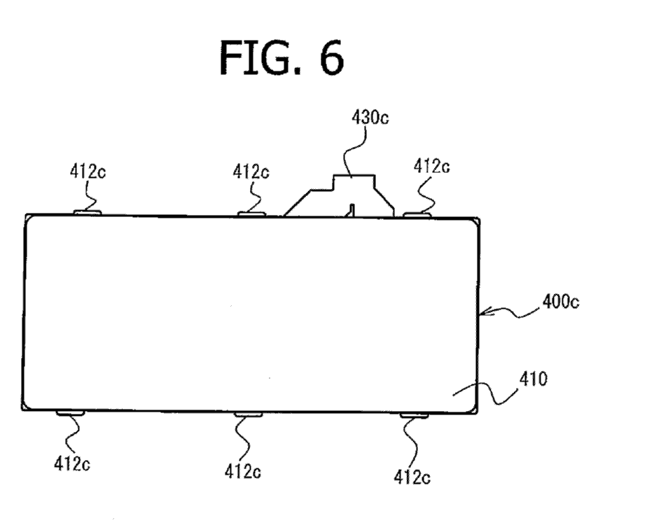

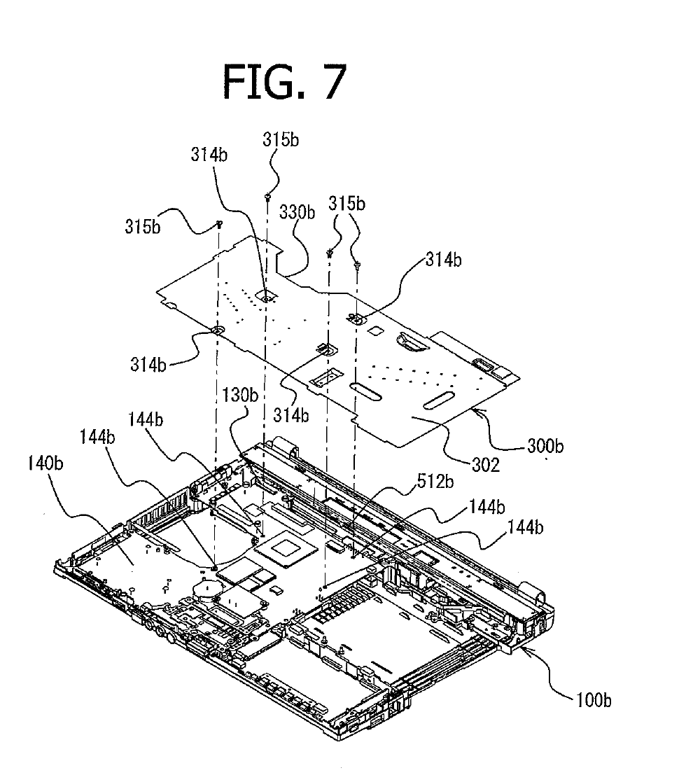

Subsequently, an adapter according to a first modification will be described. FIG. 6 is a drawing of a keyboard 400c having a different shape from the keyboard 400 viewed from the back surface side. FIG. 7 is an explanatory drawing of the adapter according to the first modification. As illustrated in FIG. 6, a cable 430c is mounted on the substrate 410 at a position shifted to the right from the center. When mounting the keyboard 400c as described above on a main body portion 100b, the adapter 300b illustrated in FIG. 7 is employed, so that the keyboard 400c is fixable to the main body portion 100b. Projections 412c of the keyboard 400c are engageable with concave portions provided on a casing of the main body portion 100b.

The main body portion 100b includes a substrate 140b on which electronic components are mounted integrated therein as illustrated in FIG. 7, and the substrate 140b is formed with four screw holes 144b. The screw holes 144b are used for fixing an adapter 300b to the casing of the main body portion 100b in cooperation with screws 315b. The adapter 300b is formed with four hole portions 314b. The hole portions 314b allow insertion of the screws 315b. The screws 315b are screwed into the screw holes 144b on the substrate 140b. Therefore, the hole portions 314b function as the main boy fixing portions for fixing the main body portion 100 to the back surface of the adapter 300b.

The adapter 300b is formed with a notched portion 330b at part of the periphery thereof. The notched portion 330b is formed to retract from a connector 130b mounted on the substrate 140b.

The notched portion 330b is provided at a position corresponding to the cable 430c. Therefore, the electrical connection between the keyboard 400c and the main body portion 100b is ensured. In other words, the notched portion 330b functions as the clearance portion for avoiding interference between the cable 430c and the adapter 300b.

As described above, normally, the design of the keyboard is modified so as to match the main body portion 100b and the keyboard is newly manufactured. More specifically, the keyboard having screw holes corresponding to the positions of the screw holes 144b of the substrate 140b is needed to be designed and manufactured. However, as illustrated in FIG. 6, by modifying the design of the adapter 300b so as to be fixable to the main body portion 100b instead of modifying the design of the keyboard, the fixation of the keyboard to the main body portion 100b is achieved without modifying the design of the keyboard 400c. Accordingly, in comparison with the case in which the keyboard is newly designed and manufactured, the manufacturing cost of the laptop personal computer is reduced.

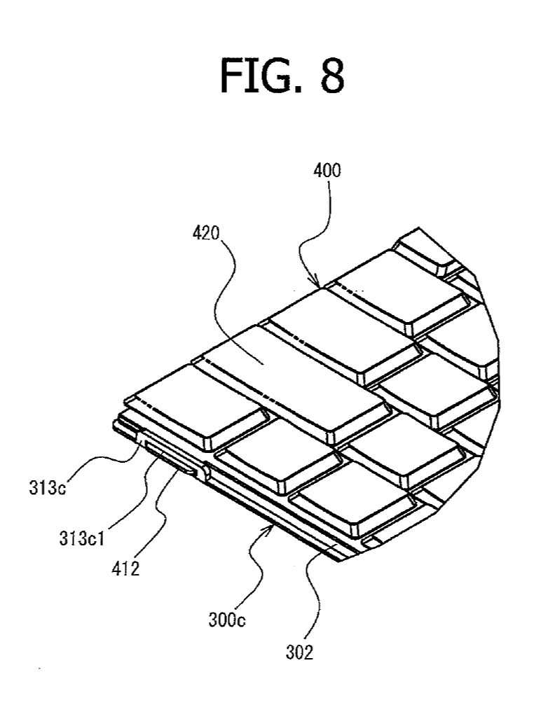

Subsequently, an adapter according to a second modification will be described. FIG. 8 is an explanatory drawing of the adapter according to the second modification. As illustrated in FIG. 8, an adapter 300c is formed with a projecting strip 313c projecting upward from the front surface 302 on the edge thereof. The projecting strip 313c is formed with an engaging hole 313c1. The engaging hole 313c1 engages the projection 412 formed on the edge of the substrate 410. A plurality of the projecting strips 313c and the projections 412 are formed on the edge of the adapter 300c and the edge of the substrate 410 respectively, although they are not illustrated in the drawing. By the engagement between the engaging holes 313c1 and the projections 412, the keyboard 400 is fixed to a front surface 302c of the adapter 300c. The adapter 300c is fixed to the main body portion by screws or claws.

By the engagement between the engaging holes 313c1 and the projections 412, the keyboard 400 is positioned with respect to the adapter 300c. Therefore, the engaging holes 313c1 and the projections 412 function as the positioning portions.

The keyboard 400 fixed to the adapter 300c may be fixed without using the fixing member 500. In other words, the keyboard 400 may be configured to be fixed to the adapter 300c by the engagement between the plurality of engaging holes 313c1 and the plurality of projections 412 without using the fixing member 500.

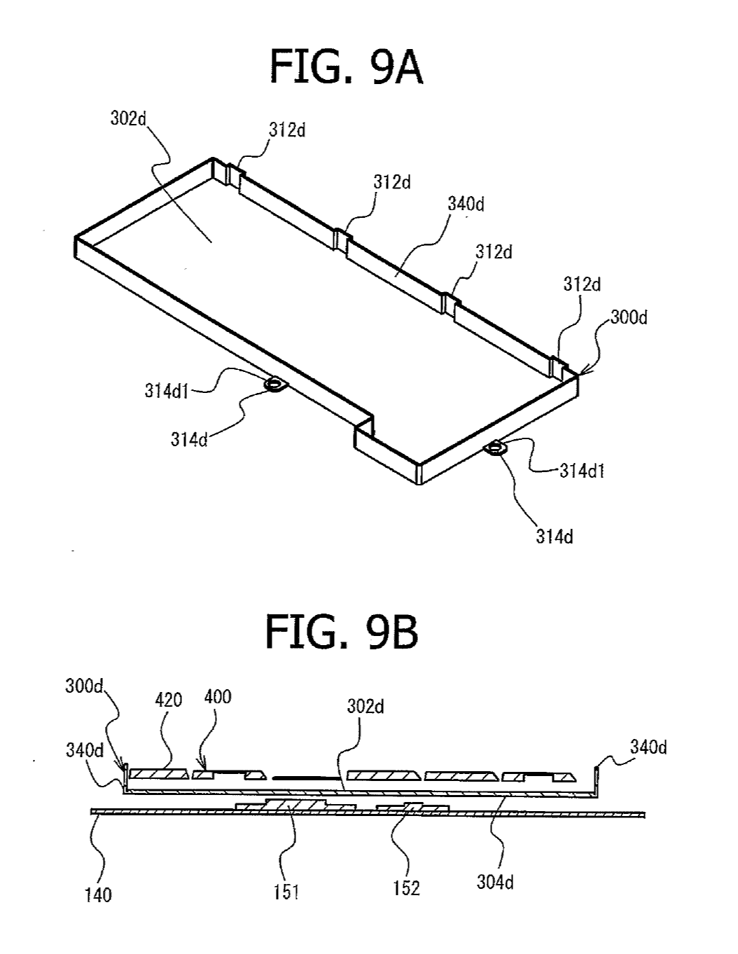

Subsequently, an adapter according to a third modification will be described. FIGS. 9A and 9B are explanatory drawings of the adapter according to a fourth modification. FIG. 9A is a perspective view of an adapter 300d. As illustrated in FIG. 9A, the adapter 300d is formed with a wall portion 340d projecting upward from a front surface 302d on the edge thereof. The wall portion 340d is formed entirely along the edge of the adapter 300d. The wall portion 340d is provided with projecting strips 314d on the outside of the side surface thereof. The projecting strips 314d each are formed with a hole portion 314d1. The adapter 300d is fixed to the main body portion 100 by screws inserted into the hole portions 314d1. Therefore, the projecting strips 314d function as the main body fixing portions for fixing the main body portion 100 to a back surface 304d of the adapter 300b.

FIG. 9B is a cross-sectional view of the adapter 300d assembled to the main body portion 100. In FIG. 9B, the structures of the keyboard 400 and the main body portion 100 are illustrated in a simplified manner. Arranged under the adapter 300d are the substrate 140 and electronic components 151, 152 mounted on the substrate 140. The wall portion 340d has a height exceeding an upper end surface of the keys 420 of the keyboard 400. In other words, the keyboard 400 fixed to the adapter 300d is surrounded by the wall portion 340d. Accordingly, even when water or dust enters through the keyboard 400, entry thereof into the interior of the main body portion 100 is prevented by the wall portion 340d. Accordingly, the risk of breakdown of the electronic components 151, 152 may be prevented. The fixation between the adapter 300d and the keyboard 400 is achieved by the fusion bonding, the adhesive agent, or the double-sided adhesive tape. Projections 312d are pressed against the main body portion 100 by the pressing portions 512 of the fixing member fixing member 500.

The fixation of the keyboard 400 to the adapter 300d may be the double-sided adhesive tape, the adhesive agent, or the fusion bonding, and may be performed by using the fixing member 500 described above.

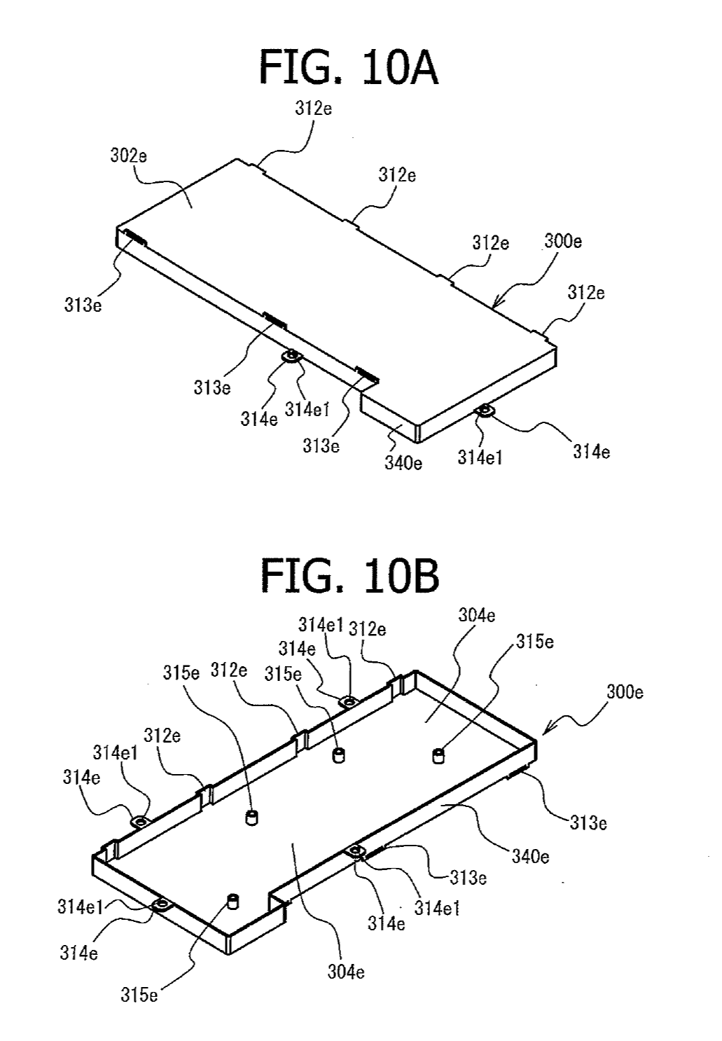

Subsequently, an adapter according to a fourth modification will be described. FIGS. 10A and 10B are an explanatory drawing of the adapter according to the fourth modification. FIG. 10A is a perspective view of an adapter 300e viewed from a front surface 302e side, and FIG. 10B is a perspective view viewed from a back surface 304e side. The adapter 300e is formed of metal. The adapter 300e is formed with a wall portion 340e projecting toward the back surface 304e side on the edge thereof. The wall portion 340e is formed entirely along the edge of the adapter 300e. The front surface 302e is formed with a plurality of projecting strips 313e projecting upward from the front surface 302e on the edge thereof. The wall portion 340e is formed with a plurality of projecting strips 314e projecting outward from the outer surface thereof. The projecting strips 314e each are formed with a hole portion 314e1. The projecting strips 314e are used for fixing the adapter 300e to the main body portion 100. The back surface 304e is formed with a plurality of pin portions 315e. The pin portions 315e are used for fixing the substrate on which the electronic components are mounted. In other words, the adapter 300e is formed so as to be capable of integrating the electronic component therein.

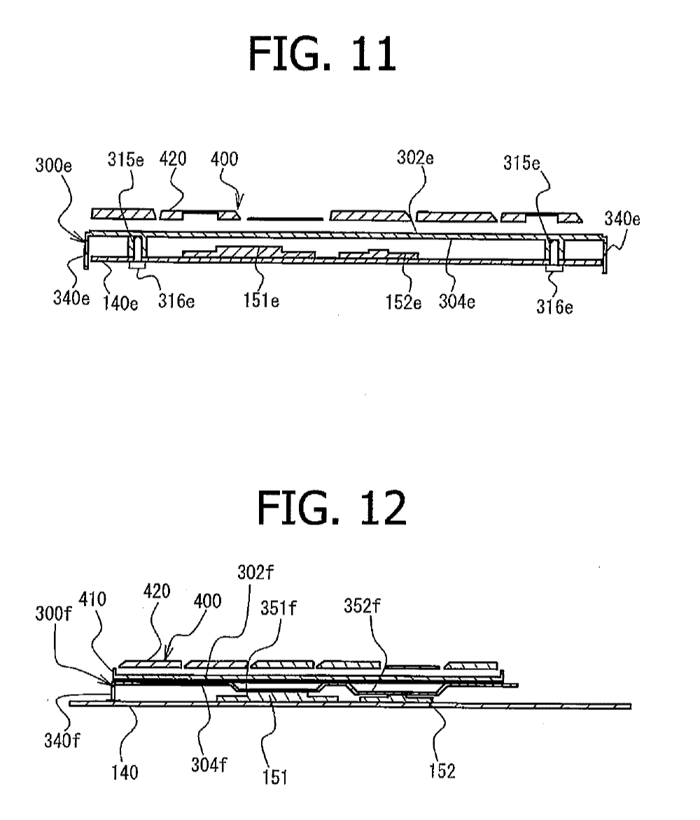

FIG. 11 is a cross-sectional view of the adapter 300e in a state in which the electronic components are integrated in the adapter 300e. Screws 316e are screwed into the pin portions 315e, and a substrate 140e is fixed to the adapter 300e. In other words, the pin portions 315e function as mounting portions for mounting the electronic components. A mounting surface of the substrate 140e opposes the back surface 304e. Electronic components 151e, 152e are mounted on the substrate 140e. Accordingly, the adapter 300e and the electronic components 151e, 152e may be integrated. Therefore, the keyboard 400, the adapter 300e, and the electronic components 151e, 152e integrated therein may be handled integrally.

Since the wall portion 340e surrounds the electronic components 151c and 152e, leakage of electromagnetic wave noise emitted from the electronic component 151e or the like to the outside may be restrained. In other words, the adapter 300e functions as a shield. The electric connection of the substrate 140e with respect to the substrate integrated in the main body portion 100 is ensured by the cable and the connector, not illustrated. The fixation between the adapter 300e and the keyboard 400 is achieved by the fusion bonding, the adhesive agent, or the double-sided adhesive tape.

The fixation of the keyboard 400 to the adapter 300e may be the double-sided adhesive tape, the adhesive agent, or the fusion bonding, and may be performed by using the fixing member 500 described above.

Subsequently, an adapter according to a fifth modification will be described. FIG. 12 is a cross-sectional view for explaining the adapter according to the fifth modification. In FIG. 12, the main body portion 100 and the keyboard 400 are illustrated in a simplified manner. As illustrated in FIG. 12, an adapter 300f is provided with a wall portion 340f projecting toward a back surface 304f on the edge thereof. The adapter 300f is provided with abutting portions 351f, 352f depressed on a front surface 302f side and projecting on the back surface 304f side. The abutting portions 351f, 352f abut against upper surfaces of the electronic components 151, 152 mounted on the substrate 140 respectively. Accordingly, heat from the electronic components 151, 152 may be received by the adapter 300f to accelerate heat discharge of the electronic components 151, 152. Therefore, the adapter 300f functions as a heat discharging panel as well. The adapter 300f is formed of metal having a good heat conducting property.

Since the wall portion 340f surrounds the electronic components 151, 152, the wall portion 340f also functions as the shield. The fixation of the keyboard 400 to the adapter 300f is achieved by the double-sided adhesive tape but may be performed by the fusion bonding, the adhesive agent, or by using the fixing member 500.

The embodiments described above are preferred examples of the present invention. However, the invention is not limited thereto, and may be modified variously without departing the scope of the present invention.

The electronic apparatus may be apparatuses other than the laptop personal computer. For example, it may be a PDA (Personal Digital Assistant) or a mobile telephone set.

The number of the projections 312, 312d, the number of the projecting strips 314d, 314e, and the number of pin portions 315e are not limited to those described above.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A keyboard adapter comprising:
a first surface for fixing a keyboard;
a second surface fixed to an apparatus body for allowing to separate with keyboard; and
a body fixing portions for fixing the apparatus body to the second surface.

2. The keyboard adapter of claim 1, further comprising a positioning portion for positioning with the keyboard.

3. The keyboard adapter of claim 1, further comprising a clearance portion for avoiding interference of a cable connecting the keyboard and an apparatus body.

4. The keyboard adapter of claim 1, wherein the first surface includes an engagement portion for fixing the keyboard.

5. The keyboard adapter of claim 1, wherein the first surface including a wall portion on the edge of the keyboard adapter, the wall portion surrounding the keyboard

6. The keyboard adapter of claim 1, the second surface including a wall portion on the edge of the keyboard adapter, the wall portion surrounding an electronic component of the apparatus body when the apparatus body is fixed to the keyboard adapter.

7. The keyboard adapter of claim 1, wherein the keyboard adapter is made by metal.

8. The keyboard adapter of claim 1, wherein the keyboard adapter is made by metal and attaches an electronic component of the apparatus body when the apparatus body is fixed to the keyboard adapter.

9. The keyboard adapter of claim 1, wherein the apparatus body includes a keyboard adapter fixing portion for fixing the keyboard adapter.

10. An electronic apparatus comprising:
a keyboard;
a apparatus body; and
a keyboard adapter including:
a first surface for fixing the keyboard,
a second surface fixed to an apparatus body for allowing to separate with keyboard, and
a body fixing portions for fixing the apparatus body to the second surface.

11. The electronic apparatus of claim 10, further comprising a fixing member for pressing the keyboard adaptor to the apparatus body, the fixing member including an apparatus body fixing portion for fixing with the apparatus body.
